(19) United States
(12) Patent Application Publication
(10) Pub. No.: US 2005/0255663 A1
(43) Pub. Date: Nov. 17, 2005

(54) Semiconductor device and method of manufacturing the same

(76) Inventors: Katsuaki Natori, Yokohama-shi (JP); Koji Yamakawa, Tokyo (JP); Hiroyuki Kanaya, Yokohama-shi (JP); Karl Hornik, Kamakura-shi (JP); Andreas Hiliger, Taipei (TW)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/856,868

(22) Filed: Jun. 1, 2004

(30) Foreign Application Priority Data
May 13, 2004 (JP) 2004-143428

(51) Int. Cl. H01L 21/20

(52) U.S. Cl. 438/396

(57) ABSTRACT

A semiconductor device according to the present invention comprises a capacitor including a lower electrode, a dielectric material, and an upper electrode. The device further comprises a first protective film which contacts the upper electrode to constitute a columnar structure of films formed by a sputtering process and a second protective film formed above the first protective film by a CVD process.

### BACKGROUND OF THE INVENTION

1. Field of the Invention

The present invention relates to a semiconductor device and a method of manufacturing the device, more specifically to a semiconductor device including a capacitor in which a dielectric material is used and a method of manufacturing the device.

2. Description of the Related Art

A ferroelectric random access memory (FeRAM), which is a nonvolatile memory using a ferroelectric thin film and in which a capacitor dielectric film of a DRAM is replaced with a ferroelectric material, is expected to be the next generation memory.

In an FeRAM, ferroelectric materials such as PZT(Pb(ZrₓTi₁₋ₓ)O₃), BIT(Bi₄Ti₃O₁₂), and SBT(SrBi₂Ta₂O₉) are used as a capacitor dielectric film. Any of the materials includes a crystalline structure based on a perovskite structure including an oxygen octahedron which is a basic structure. Unlike a conventional Si oxide film, when these materials are in amorphous state, ferroelectricity is not revealed as one of characteristics, and therefore the materials cannot be used in amorphous. Therefore, steps of crystallizing the materials such as crystallization heat treatment at a high temperature, or in-situ crystallization process at a high temperature is required. In general, a temperature of at least 400 to 700° C. is required for the crystallization depending on the material. Examples of a film forming method include an MOCVD process, a sputtering process, and a chemical solution deposition (CSD) process.

For the FeRAM capacitor in which the above-described ferroelectric material is used, even when the properties just after forming a capacitor film are satisfactory, there are problems that process damage occurs by diffusion of H in subsequent processes such as an RIE process, an interlevel film forming and wiring processes, a sintering process, and a molding process, thus the capacitor properties are degraded. Then, heat treatment in an oxygen-containing atmosphere is required in order to repair the damage.

Additionally, for the capacitor structure, with higher integration, to replace an offset type structure in which an upper electrode of the capacitor is connected to an active region of a transistor, in recent years, development of a capacitor on plug (COP) structure in which the capacitor is disposed on a plug in order to prepare a higher-density FeRAM has been advanced. Since a plug structure formed of W or Si and connected to an active region of the transistor is disposed immediately under the capacitor, a cell size can be reduced in the same manner as in stacked capacitor of DRAM.

In this structure, however, a plug material right under the capacitor is oxidized to raise contact resistance during the heat treatment for repairing the damage in the oxygen-containing atmosphere. In the worst case, there is a problem that peeling occurs. To avoid this, attempts have been made to form barrier layers such as TiAlN, TiN, and TaSiN and to use electrode materials such as IrO₂, Ir, RuO₂, and Ru. However, in this case, there are disadvantages that the structure is complicated. Since resistance to the heat treatment cannot be said to be high, it is essential to lower the temperature and reduce the time in the heat treatment.

To solve the problem, a protective film for reducing damage is used in order to reduce the damage to the capacitor in the post-process. In Jpn. Pat. Appln. KOKAI Publication No. 2001-36026, since an Al oxide film is used as the protective film in a capacitor upper layer portion, a capacitor cell avoiding damage is obtained. Examples of a method of manufacturing the Al oxide film include a sputtering process, a chemical vapor deposition (CVD) process, and the like. In Jpn. Pat. Appln. KOKAI Publication No. 2002-43541, an atomic layer deposition (ALD) process higher in step coverage property is used for fine processing with higher integration.

However, since trimethyl-aluminum (TMA) having a high reducing property is used as a source gas in the ALD process that is one of the CVD processes, there is a problem that the capacitor properties are degraded at the time of the film formation.

Additionally, a capacitor preparing process has also been proposed in which a damascene process is used for the purpose of reducing the RIE processing damage to the capacitor. However, in the process in which CMP is used, the heat treatment is sometimes performed in a state in which the oxide film contacts with a dielectric film or a ferroelectric film, and therefore reaction in the corresponding portion raises a problem. For example, PZT and SiO₂ have a problem that lead glass is formed by heat and the contact portion is remarkably degraded.

### BRIEF SUMMARY OF THE INVENTION

According to an aspect of the invention, there is provided a semiconductor device comprising a capacitor including a lower electrode, a dielectric material, and an upper electrode, the device further comprising: a first protective film which contacts the upper electrode to constitute a columnar structure of films formed by a sputtering process; and a second protective film formed above the first protective film by a CVD process.

According to another aspect of the invention, there is provided a method of manufacturing a semiconductor device comprising a capacitor including a lower electrode, a dielectric material, and an upper electrode, the method comprising: forming a first protective film which contacts the upper electrode by a sputtering process; and forming a second protective film above the first protective film by a CVD process.

### BRIEF DESCRIPTION OF THE SEVERAL VIEWS OF THE DRAWING

FIG. 1A is a sectional view showing a manufacturing process of FeRAM according to an embodiment of the present invention;

FIG. 1B is a sectional view showing the manufacturing process of the FeRAM according to the present embodiment;

FIG. 1C is a sectional view showing the manufacturing process of the FeRAM according to the present embodiment;

FIG. 2 is a sectional view showing a major portion of the FeRAM manufactured by the manufacturing process of the present embodiment;

FIG. 3 shows a sectional image indicating a columnar structure of a protective film according to the present embodiment;

FIG. 4 is a diagram showing hysteresis characteristics in an FeRAM capacitor manufactured by the present embodiment;

FIG. 5A is a diagram showing the hysteresis characteristics in the FeRAM capacitor according to the present embodiment, in which an Al₂O₃ film formed by a CVD process is used in all the protective films; and

FIG. 5B is a diagram showing the hysteresis characteristics in the FeRAM capacitor according to the present embodiment, in which the Al₂O₃ film formed by a sputtering process is used in all the protective films.

### DETAILED DESCRIPTION OF THE INVENTION

An embodiment will hereinafter be described with reference to the drawings.

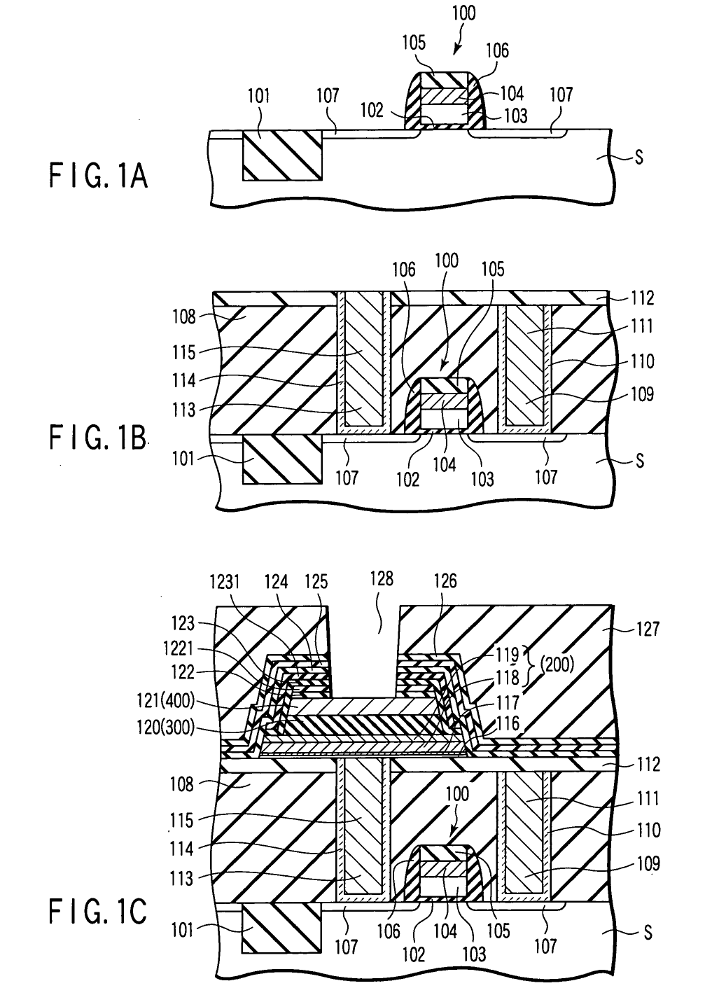

FIGS. 1A, 1B, and 1C are sectional views showing a manufacturing process of FeRAM according to the present embodiment. In the present embodiment, a COP type FeRAM cell using tungsten in a plug material positioned under a capacitor will be described.

First, as shown in FIG. 1A, a trench for isolating devices is formed in a region other than a transistor active region in a P type Si substrate S surface, then SiO₂ is buried in the trench to form an isolation 101 (shallow trench isolation). Subsequently, a transistor for performing a switching operation is formed.

First, a thermal oxide film 102 having a thickness of about 6 nm is formed all over the surface of the Si substrate, an n+ type polycrystalline silicon film 103 doped with arsenic is subsequently formed all over the surface of the oxide film 102, a WSiₓ film 104 is further formed on the polycrystalline silicon film 103, and a nitride film 105 is formed on the WSiₓ film 104. Thereafter, the polycrystalline silicon film 103, WSiₓ film 104, and nitride film 105 are processed by conventional photolithography process and RIE process to form a gate electrode 100.

Furthermore, a nitride film 106 is deposited, and spacers are disposed on side walls of the gate electrode 100 by leaving the side walls by RIE. Moreover, although detailed description of the process is omitted, source/drain 107 is formed by ion implantation processes and heat treatments.

Next, as shown in FIG. 1B, after depositing a CVD oxide film 108 all over the surface, once the surface is planarized by a CMP process, and a contact hole 109 connected to one of the source/drain 107 of a transistor is formed. Thereafter, a thin titanium film is deposited by a sputtering or CVD process, and a heat treatment is performed in a foaming gas to form a TiN film 110. Subsequently, a CVD tungsten 111 is deposited all over the surface, and the tungsten 111 is removed from a region other than the contact hole 109 by the CMP process to bury tungsten in the contact hole 109.

Thereafter, a CVD nitride film 112 is deposited all over the surface, further a contact hole 113 connected to the other source/drain 107 of the transistor is formed, similarly a TiN film 114 is formed, and tungsten 115 is buried in the contact hole 113 to form a plug connecting to a capacitor.

Thereafter, as shown in FIG. 1C, a silicon carbide film 116 having a thickness of 10 nm is deposited all over the surface of the CVD nitride film 112 by a sputtering process, and subsequently a titanium film 117 having a thickness of about 3 nm is deposited all over the surface of the silicon carbide film 116 by a sputtering process. Thereafter, an iridium film 118 having a thickness of 30 nm and a first platinum film 119 having a thickness of 20 nm constituting a capacitor lower electrode 200 are formed all over the surface of the titanium film 117 by sputtering processes.

Furthermore, a PZT film 120 constituting a capacitor dielectric film 300 is formed on the first platinum film 119 by a sputtering process, then the PZT film 120 is once crystallized by a rapid thermal anneal (RTA) in an oxygen atmosphere. Thereafter, a second platinum film 121 constituting a capacitor upper electrode 400 is formed on the PZT film 120 by the sputtering process.

Thereafter, an Al₂O₃ film is formed as a protective film 122 on the platinum film 121 by a sputtering process. The film forming temperature is set at 350° C., and the film thickness is set to 10 nm. Subsequently, a CVD oxide film 1221 is deposited as a processing mask material on the protective film 122, and the CVD oxide film 1221 is patterned by the photolithography and RIE processes. After removing a photo resist, the protective film 122, second platinum film 121, and PZT film 120 are etched by RIE processes.

Next, the Al₂O₃ film is formed as a protective film 123 by the sputtering process. The film forming temperature is set at 350° C., and the film thickness is set to 10 nm. Subsequently, a CVD oxide film 1231 is deposited as the processing mask material on the protective film 123, and the protective film 123, first platinum film 119, iridium film 118, titanium film 117, and silicon carbide film 116 are patterned by a combination of the photolithography and RIE processes to complete the forming of the capacitor.

Thereafter, an Al₂O₃ film is formed as a protective film 124 by an ALD process which is one of the CVD processes. The film forming temperature is set at 200° C., and the film thickness is set to 10 nm. Subsequently, a CVD oxide film 125 is deposited on the protective film 124 by 50 nm, and another Al₂O₃ film is formed as a protective film 126 by the ALD process. The film forming temperature is set at 200° C., and the film thickness is set to 10 nm.

Next, a CVD oxide film 127 is deposited all over the surface to cover the capacitor, the surface is planarized by the CMP, the CVD oxide film 127 is patterned by the photolithography and RIE processes, and a contact hole 128 to the second platinum film 121 is formed. Subsequently, heat treatment is performed at about 600° C. in an oxygen atmosphere in order to repair the damage in the PZT film 120 caused during the processing.

Thereafter, although not shown, the FeRAM is completed through steps of forming drive and bit lines and further disposing upper layer metal wirings.

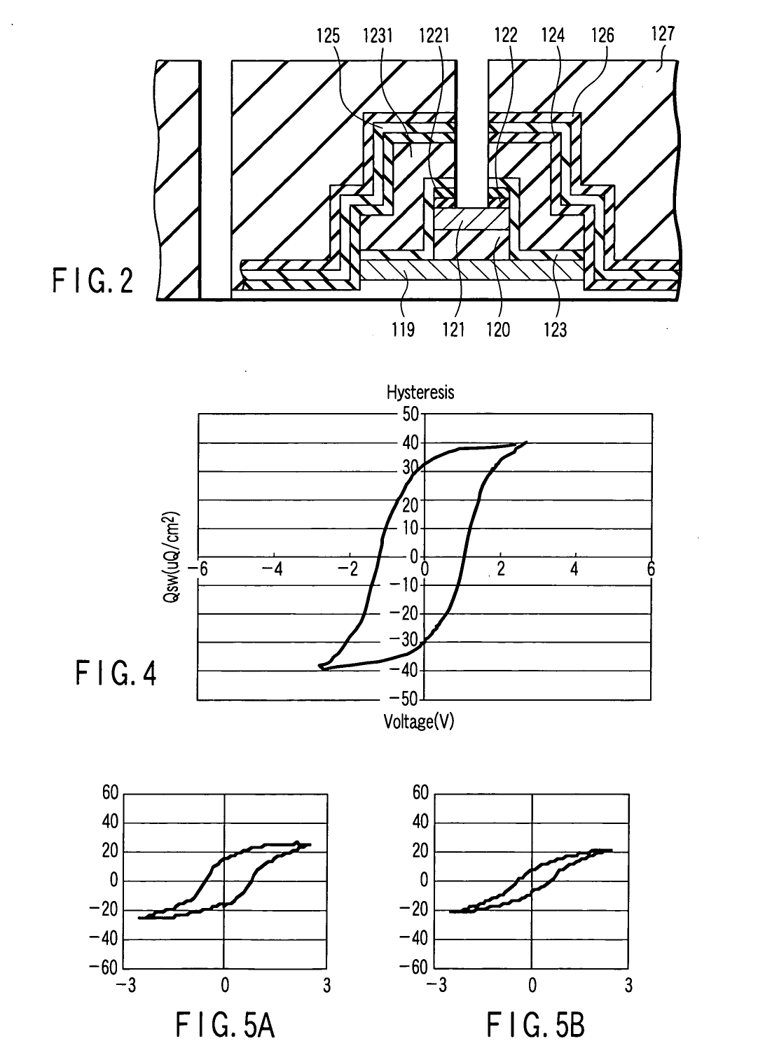

FIG. 2 is a sectional view showing a major portion of the FeRAM manufactured by the manufacturing process of the present embodiment. As shown in FIG. 2, the protective film 122 is formed on the upper surface of the second platinum film 121 (upper electrode) by the sputtering process, and the sputtered protective film 123 is formed above the protective film 122, and on the side surfaces of the second platinum film 121, the side surfaces of the PZT film 120 (dielectric film), and the upper surface of the first platinum film 119 (lower electrode). Furthermore, the protective film 124 by the ALD process is formed above the protective film 123 and on the side surfaces of the first platinum film 119, and the protective film 126 by the ALD process is formed above the protective film 124.

As described above, the Al₂O₃ film formed by the sputtering process is used in the protective films 122, 123 (first protective film), and the Al₂O₃ film formed by the ALD process is used in the protective films 124, 126 (second protective film), so that it is possible to reduce the damage to the PZT film 120 caused during the processing, the depositing of the CVD oxide film, and the forming of the Al₂O₃ film by the ALD process.

It is to be noted that in the present embodiment, the sputtered film is used to form both the protective films 122, 123, but it has been confirmed that the effect is produced even with the use of the sputtered film only in the protective film 122. For the capacitor materials, the PZT film is used in the ferroelectric film, and platinum is used in the upper and lower electrodes, but the capacitor materials are not limited to these materials. For example, an SBT film may also be used in the ferroelectric film. Moreover, iridium, ruthenium, or compound conductor such as strontium ruthenium oxide may also be used as the electrode.

In the present embodiment, there are provided a new semiconductor device and a method of manufacturing the device in which capacitor properties are remarkably hardly degraded in a structure using the protective film for the purpose of avoiding or reducing damage caused by the RIE or plasma CVD process in the steps of forming the capacitor as in the capacitor process in an FeRAM or DRAM including the ferroelectric capacitor.

In the present embodiment, these problems are solved, a capacitor dielectric film superior in properties can be formed, and moreover thermal stability with an underlying plug can also be achieved. Accordingly, it is possible to provide semiconductor devices which are highly reliable, fine patterned, and highly integrated, such as FeRAMs and DRAMs. The effect will hereinafter concretely be described.

An Al oxide film has a hydrogen-resistant barrier property, and is effective as the protective film which prevents the capacitor properties from being degraded in the RIE process, plasma CVD process, and sintering process. The forming of the Al oxide film by the CVD process is satisfactory in step coverage property, and particularly the atomic layer deposition (ALD) process is superior in step coverage property and film thickness controllability. However, when the Al oxide film is formed by the ALD process, trimethyl-aluminum (TMA) is used as a source gas. Therefore, when the film is directly formed on the capacitor upper electrode or the ferroelectric material, the capacitor properties are degraded by hydrogen generated from TMA.

However, when the protective film directly contacting the capacitor upper electrode or the ferroelectric material is formed using the sputtering process, and another protective film above is formed using the ALD process satisfactory in the step coverage properties as in the present embodiment, a barrier property against hydrogen is enhanced, and it is possible to form the Al oxide film as the protective film without degrading the capacitor properties. It is possible to obtain a ferroelectric capacitor cell avoiding post-process damage and having superior properties.

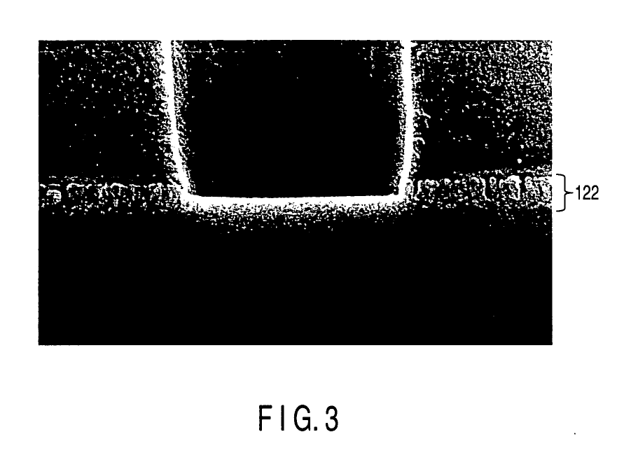

Furthermore, when the film forming temperature in forming the Al oxide film by the sputtering process is set at 350° C., the protective films 122, 123 that are Al oxide films include a columnar grain structure as shown by a sectional image in FIG. 3. At this time, a grain size of the Al₂O₃ film is 20 to 50 nm. Therefore, since hydrogen is trapped at the grain boundary caused by the densified columnar structure in the protective films 122, 123, permeability for hydrogen decreases, thus barrier properties are enhanced, and it is possible to further reduce the damages in the post-process. It is to be noted that the film forming temperature for forming the columnar structure is in a range of not less than 200° C. and not more than 600° C. The other protective films 124, 126 constitute an amorphous structure.

FIG. 4 is a diagram showing hysteresis characteristics in the FeRAM capacitor manufactured by the present embodiment. As seen from FIG. 4, satisfactory hysteresis characteristics are obtained.

FIGS. 5A, 5B are diagrams showing the hysteresis characteristics in the FeRAM capacitor. FIG. 5A is a diagram showing a case where the Al₂O₃ film formed by the CVD process is used in all the protective films 122, 123, 124, 126, and FIG. 5B is a diagram showing a case where the Al₂O₃ film formed by the sputtering process is used in all the protective films 122, 123, 124, 126. It is seen that the hysteresis characteristics by the present embodiment shown in FIG. 4 are satisfactory as compared with FIGS. 5A, 5B.

When all the protective films are formed by the CVD process as shown in FIG. 5A, PZT is reduced by hydrogen caused from TMA that is a raw material in the CVD process in an initial stage of the forming of the Al₂O₃ film directly on the side surfaces of the upper electrode and PZT film, and the capacitor properties are degraded. The properties in FIG. 5A are degraded due to the damage caused by the CVD process as compared with that in FIG. 4.

When all the protective films are formed by the sputtering process as shown in FIG. 5B, there is no damage as the damage in the CVD process. However, H₂ barrier property of the sputtered Al₂O₃ film is low and the step coverage property is also not good. Accordingly, a portion in which Al₂O₃ cannot be formed on the film is generated, H₂ diffuses from the portion to the capacitor, and the capacitor properties are degraded. The properties in FIG. 5B are degraded due to the low barrier property as compared with that in FIG. 4.

On the other hand, in the case of FIG. 4, first the sputtering process is used in forming the Al₂O₃ film directly on the side surfaces of the upper electrode and PZT film susceptible to the process damages. When another film is formed above the film, the ALD process is used to raise the barrier property and to completely cover the capacitor, and accordingly damage by the post-process can be effectively prevented. Therefore, in FIG. 4, satisfactory properties are obtained as compared with FIGS. 5A, 5B.

As described above, according to the present embodiment, it is possible to provide a ferroelectric memory which is fine patterned, highly densified, and highly integrated.

It is to be noted that the mode of the present invention is not limited to the above-described embodiment, and can appropriately be modified and implemented in such a range that the scope is not changed. For example, the mode of the present invention is not limited to a ferroelectric memory, and can also be applied to a DRAM in which a ferroelectric capacitor is used.

In accordance with the embodiment of the present invention, there can be provided a semiconductor device and a method of manufacturing the device in which the damage in the post-process can be reduced, and a capacitor having satisfactory electrical properties and a semiconductor device including the capacitor can be realized. That is, since two types of protective film are used in the capacitor structure, degradation of the capacitor properties is avoided in forming the protective film, and it is possible to avoid the property degradation caused during the forming of the interlevel films and by RIE.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A semiconductor device comprising a capacitor including a lower electrode, a dielectric material, and an upper electrode, the device further comprising:
a first protective film which contacts the upper electrode to constitute a columnar structure of films formed by a sputtering process; and
a second protective film formed above the first protective film by a CVD process.

2. The semiconductor device according to claim 1, wherein the CVD process is an ALD process.

3. The semiconductor device according to claim 1, wherein the first protective film contacts the dielectric material.

4. The semiconductor device according to claim 2, wherein the first protective film contacts the dielectric material.

5. The semiconductor device according to claim 1, wherein an Al oxide is used in the first and second protective films.

6. The semiconductor device according to claim 2, wherein an Al oxide is used in the first and second protective films.

7. A method of manufacturing a semiconductor device comprising a capacitor including a lower electrode, a dielectric material, and an upper electrode, the method comprising:
forming a first protective film which contacts the upper electrode by a sputtering process; and
forming a second protective film above the first protective film by a CVD process.

8. The method according to claim 7, wherein the CVD process is an ALD process.

9. The method according to claim 7, wherein the first protective film contacts the dielectric material.

10. The method according to claim 8, wherein the first protective film contacts the dielectric material.

11. The method according to claim 7, wherein an Al oxide is used in the first and second protective films.

12. The method according to claim 8, wherein an Al oxide is used in the first and second protective films.
